(19) United States
(12) Patent Application Publication
(10) Pub. No.: US 2005/0095745 A1
(43) Pub. Date: May 5, 2005

(54) High-density packaging of integrated circuits

(76) Inventor: Itzhak Sapir, Irvine, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/829,664

(22) Filed: Apr. 22, 2004

Related U.S. Application Data
(63) Continuation of application No. 09/616,432, filed on Jul. 14, 2000, now abandoned.
(60) Provisional application No. 60/144,433, filed on Jul. 16, 1999.

(51) Int. Cl. H01L 21/50

(52) U.S. Cl. 438/106; 257/686

(57) ABSTRACT

An integrated circuit constructed on a folded integrated circuit is described. The folded integrated circuit has a much smaller form-factor than the original (unfolded) circuit and is thus more suitable for use in miniature devices, such as, for example, electronic camera, electronic-film cartridge, cellular telephone, handheld computer, handheld digital music device, portable devices, handheld devices, and the like. In one embodiment, the integrated circuit is folded by thinning an area of the substrate such that the thinned area of the substrate becomes flexible. Conducting traces on the upper surface of the substrate connect an active region on one side of the thinned area to an active region on the other side of the thinned area. The substrate is folded at the thinned area to thereby reduce the size of the substrate. In one embodiment, a heat-sink is inserted between the folds to carry heat away from the substrate.

### RELATED APPLICATIONS

The present application is a continuation of application Ser. No. 09/616,432, filed Jul. 14, 2000, which claims priority under 35 U.S.C. 119(e) from U.S. Provisional Application No. 60/144,433, filed on Jul. 17, 1999, titled “E-FILM TECHNOLOGY,” both of which are hereby incorporated by reference.

### BACKGROUND OF THE INVENTION

1. Field of the Invention

The invention relates to techniques for construction of densely packed integrated circuits using folded silicon substrates.

2. Description of the Related Art

An integrated circuit is a device consisting of many interconnected transistors and other components fabricated on a (typically) silicon wafer. The silicon wafer is known as the “substrate”. Different areas of the substrate are “doped” with other elements to make either “P-type” or “N-type” regions, and conducting tracks are placed in layers over the surface. The die is then typically connected into a package using gold wires that are welded to connectors (e.g., pads, pins, balls, etc.) usually found around the outside of the die. Integrated circuits can generally be classified as analog, digital, or hybrid (both analog and digital on the same chip) circuits. The small size of the transistors and other elements on the integrated circuits allows high speed, low power dissipation, and reduced manufacturing cost compared with board-level integration.

The first integrated circuits contained only a few transistors. Small Scale Integration (SSI) brought circuits containing transistors numbered in the tens. Later, Medium Scale Integration (MSI) contained hundreds of transistors. Further development resulted in Large Scale Integration (LSI) (thousands), and VLSI (hundreds of thousands and beyond). In 1986 the first one megabyte Random Access Memory (RAM) was introduced which contained more than one million transistors.

LSI circuits began to be produced in large quantities around 1970 for computer main memories and pocket calculators. For the first time it became possible to fabricate a Central Processing Unit (CPU) or even an entire microprocessor on a single integrated circuit. The most extreme technique is wafer-scale processing which uses whole uncut wafers as components.

In 1973, Gordon Moore, one of Intel's founders, observed that the number of transistors integrated on a single silicon chip doubled every 18 months. This observation led him to predict that the number of transistors integrated on leading edge circuits would continue to double every 18 months until fundamental physical limits are reached. The accuracy of this prediction over the past 25 years was such, that it is being referred to as “Moore's law”, even though there was no physical proof or derivation involved, just simple observation. The demand for faster, cheaper and more versatile circuits has given the electronics industry the incentive to increase the transistor count and produce complex and sophisticated integrated circuit architectures.

In the past 25 years, microchip fabrication technology has experienced dramatic progress, overcoming previous feature-size limitations in a number of ways. For example, improvements in optical lithography, including the use of light of increasingly smaller wavelength in parallel with the development of higher quality lenses and filters, has enabled the patterning of ever-smaller and ever-faster transistors on the silicon wafer. As transistors became faster, interconnection delays started to become significant. The thinner wiring used to accommodate such small transistors had a very high resistance and hence an unacceptably high propagation delay due to slow risetimes. Multi-layer wiring schemes were used to solve this problem, in part by implementing thicker low-delay wires to join components far away (while still using thin high-density wires to join adjacent components), and in part by placing more and more functionality on one chip (instead of several chips). Placing more functionality on one chip reduced the propagation delay by keeping the interconnections short, and it reduced chip size and power requirements by obviating the need for output buffer amplifiers.

Although many of the manufacturing principles used to build the first integrated circuits are still used today, the technological advancements mentioned above enabled the industry to successfully scale down the components of an integrated circuit to impressive levels. By way of example, the Intel 4004, released in 1971 contained 2300 transistors, whereas a modern Pentium chip contains about 6 million transistors. With nearly every new chip generation, transistors are scaled down by a factor of approximately 0.7. This means that in each new generation, each transistor takes up only half of the area, uses only one third of the power, and is 1.4 s time faster than the transistors in the previous generation.

Unfortunately, these impressive reductions in transistor size have not been sufficient to keep up with the demand for more transistors on each chip. In order to provide enough space for all of the transistors needed on a modern integrated circuit, the designers have also been forced to increase the size of the integrated circuits. Better manufacturing processes have allowed designers to increase the number of transistors on a circuit by dramatically increasing the size of the integrated circuits without sacrificing production yields. Thus, the size of the above-mentioned Pentium chip is much larger than the size of the Intel 4004 chip.

The size of an integrated circuit chip is typically not a serious problem when the chip is placed in an automobile, desktop computer, or other relatively large device. However, the size of the chip is of paramount importance when the chip is placed in a miniature device, such as a portable or handheld device. In many circumstances, the size of the conventional planar integrated circuit is inherently incompatible with the form-factor of the device in which the circuit must be installed.

### SUMMARY OF THE INVENTION

The present invention solves these and other problems by providing a technique for folding a relatively large substrate to produce an integrated circuit having a much smaller form-factor than the original (unfolded) circuit. The smaller form-factor is suitable for installation in miniature devices, such as, for example, electronic cameras, electronic-film cartridges, cellular telephones, handheld computers, handheld digital music devices, portable devices, handheld devices, and the like.

In one embodiment, the integrated circuit is folded by thinning an area of the substrate such that the thinned area of the substrate becomes flexible. Conducting traces on the upper surface of the substrate connect one or more elements in an active region on one side of the thinned area to one or more elements in an active region on the other side of the thinned area. The substrate is folded at the thinned area to thereby reduce the size of the substrate. In one embodiment, a heat sink is inserted between the folds to carry heat away from the substrate. In one embodiment, an inter-fold plate is inserted between the folds to maintain a desired radius of curvature at the folds.

In one embodiment, the substrate is folded such that only one active region remains exposed. In one embodiment, the substrate is folded such that a first and a last active region remain exposed. In one embodiment, the substrate is folded such that no active regions remain exposed. In one embodiment, when no active regions remain exposed, conducting pads to provide for external connections are provided on an extension of one of at least one of the folds.

### DESCRIPTION OF THE FIGURES

The advantages and features of the disclosed invention will readily be appreciated by persons skilled in the art from the following detailed description when read in conjunction with the drawings listed below.

FIG. 1 illustrates a typical packaged integrated circuit having a substrate with one or more contact pads connected to external contacts.

FIG. 2 shows a silicon substrate wherein various areas of the substrate have been electrically isolated from one another by etching trenches into the silicon substrate and filling the trenches with an insulating material to form isolated regions.

FIG. 3 shows the substrate from FIG. 2 wherein the isolated regions have been doped to produce an N-channel well and a P-channel well.

FIG. 4 shows the substrate from FIG. 3 after a thin insulating layer has been deposited the wells on the surface of the substrate and a conducting layer has been deposited on top of the insulating layer.

FIG. 5 shows the substrate from FIG. 4 after the conducting layer and the insulating layer have been etched to form gates for a transistor over the N-channel well and the P-channel well.

FIG. 6 shows the substrate from FIG. 5 wherein N-channel source and drain regions have been doped into the P-channel well, and wherein a P-channel source and drain regions have been doped into the N-channel well.

FIG. 7 shows the substrate from FIG. 6 after a protective insulating layer has been provided around each gate and a conducting cap has been deposited on the source, gate, and drain of each transistor.

FIG. 8 shows the substrate from FIG. 7 after a multi-layer interconnection structure has been produced on top of the substrate to connect the various transistors and other electronic components together and to create conducting pads for external connections.

FIG. 9 shows a silicon substrate having multiple active regions connected by conductor regions.

FIG. 10 shows the silicon substrate of FIG. 9 after the thickness of the silicon substrate has been reduced in a portion of the conductor regions.

FIG. 11 shows the silicon substrate of FIG. 10 partway through the folding process wherein at least one of the active regions is “folded outward.”

FIG. 12 shows the silicon substrate of FIG. 11 at the completion of the folding process.

FIG. 13 shows the silicon substrate of FIG. 10 part way through the folding process wherein all of the active regions are “folded inward.”

FIG. 14 shows a silicon substrate having multiple active regions configured to be folded such that a contact region of at least one of the inner regions is exposed.

FIG. 15 shows a silicon substrate having multiple active regions configured to be folded in several directions.

In the drawings, the first digit of any three-digit number generally indicates the number of the figure in which the element first appears. Where four-digit reference numbers are used, the first two digits indicate the figure number.

### DETAILED DESCRIPTION

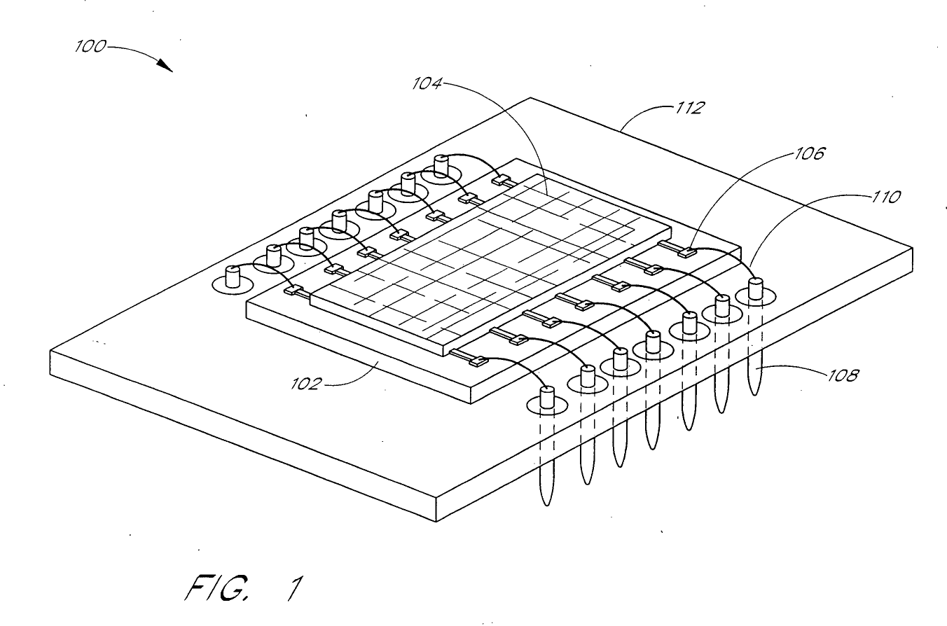

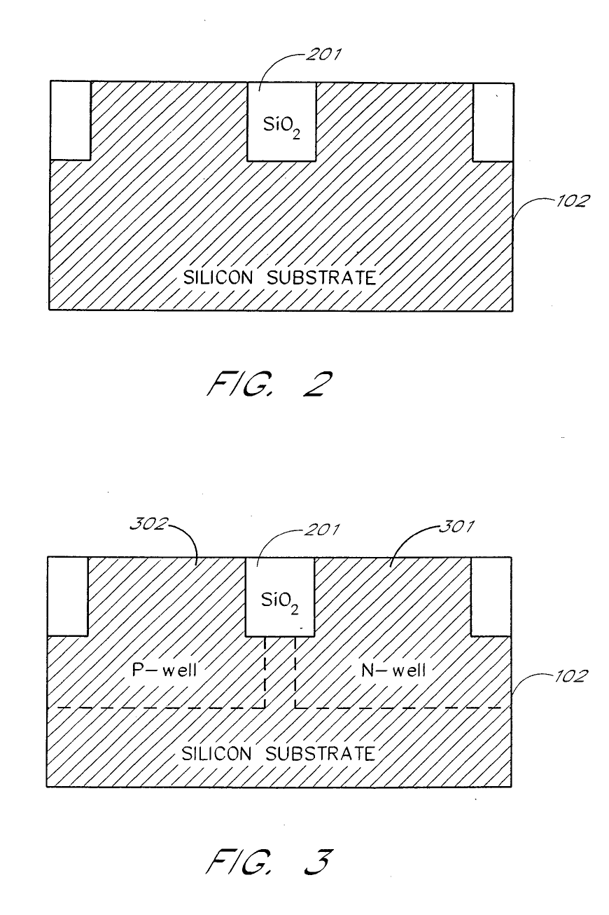

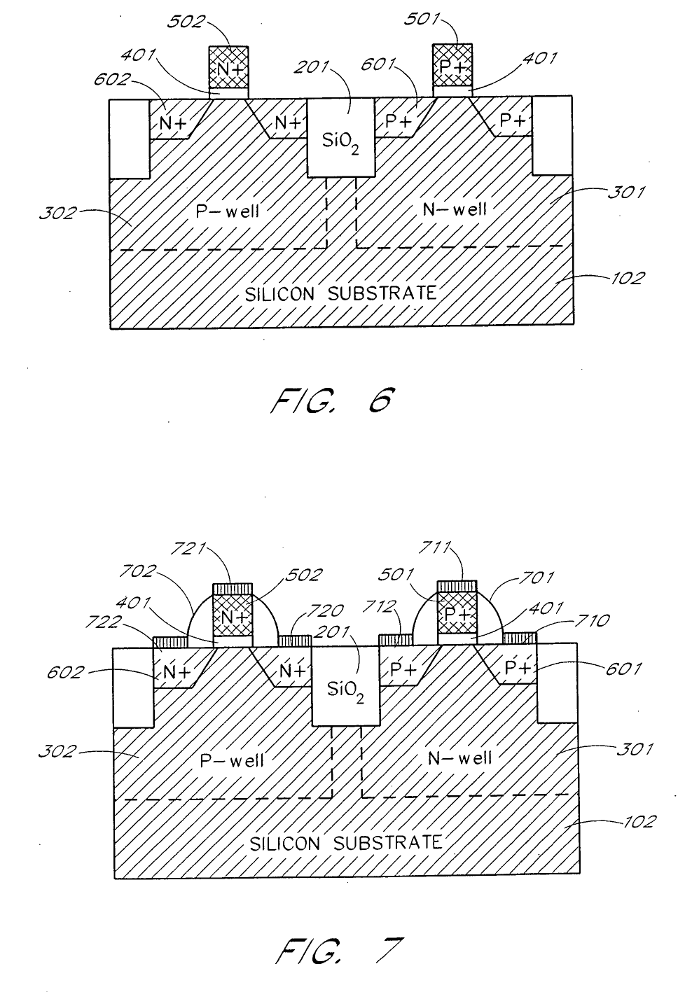

FIG. 1 shows a typical packaged integrated circuit 100. The integrated circuit 100 includes a silicon substrate 102 having an active region 104. The active region 104 includes various electronic components (e.g., transistors, resistors, capacitors, etc.) formed by doping and lithography processes (such as, for example, the processes described in connection with FIGS. 2-8). The substrate 102 is attached to a carrier 112. The carrier 112 has one or more contacts, such as a contact pin 108. A wire 110 is attached to the pin 108 and to a contact pad 106 deposited on the substrate 102. One or more conducting traces provide electrical connection between the contact pad 106 and the components in the active region 104. For convenience, and not by way of limitation, the substrate in the following disclosure is described as being made of silicon. One of ordinary skill in the art will recognize, however, that the integrated circuit substrate can be made of other elements, alloys, or compounds, including, for example, gallium arsenide, semiconductors, dielectrics, sapphire, ceramics, crystals, or other materials.

The current favorite in integrated circuit manufacturing technology is CMOS (Complementary Metal Oxide Semiconductor) technology, used in nearly all of today's commercial microchips. Manufacturing modern CMOS circuits is a complex multi-level process, where transistors are formed on a thin slice of pure silicon wafer. FIGS. 2-8 illustrate the integrated circuit manufacturing process used for an integrated circuit having 0.25 micron features. The process shown in FIGS. 2-8 is provided by way of illustration and not limitation. One skilled in the art will recognize that the present invention can be used with integrated circuits of various feature sizes and circuit types, including, for example, MOS, NMOS, ECL, TTL, etc.

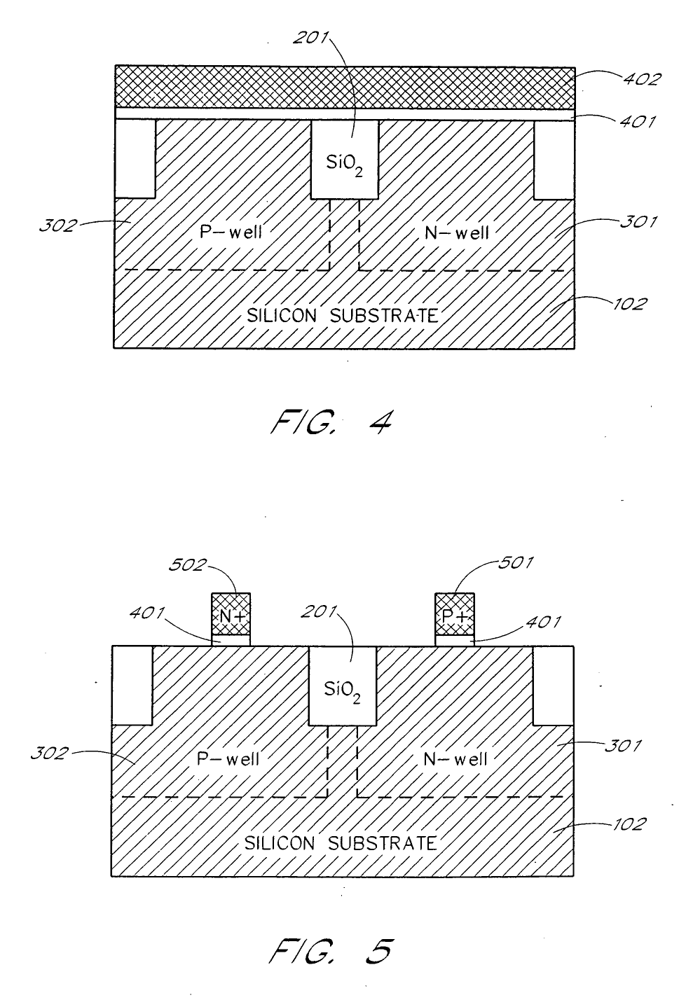

FIG. 2 shows the silicon substrate 102 wherein the various areas of the substrate where components (e.g., transistors) will be produced are isolated from one another by etching trenches into the silicon substrate 102 and filling the trenches with an insulating material, such as, for example, SiO₂ to form insulated trenches, such as, for example, an insulating trench 201. To form the basis for P-channel and N-channel transistors, P-type and N-type wells are created by adding appropriate impurities to the silicon as shown in FIG. 3. FIG. 3 shows an N-channel well 301 and a P-channel well 302.

As shown in FIG. 4, an extremely thin insulating layer 401 (typically formed using SiO₂) is then created over the wells on the surface of the substrate 102. A conducting layer 402 (typically comprising polysilicon) is then added on top of the insulating layer 401. The conducting layer 402 and the insulating layer 401 are used to form the transistor gates. An optical lithography process is used to etch a pattern in the insulating layer 401 and the conducting layer 402 to generate the gates. FIG. 5 shows a gate 501 over the N-channel well 301 and a get 502 over the P-channel well 302. The next step is to add additional N-type and P-type regions around the gates to form the source and drain of the transistors. FIG. 5 shows a P-type region 601 around the gate 501 and an N-type region 602 around the gate 502.

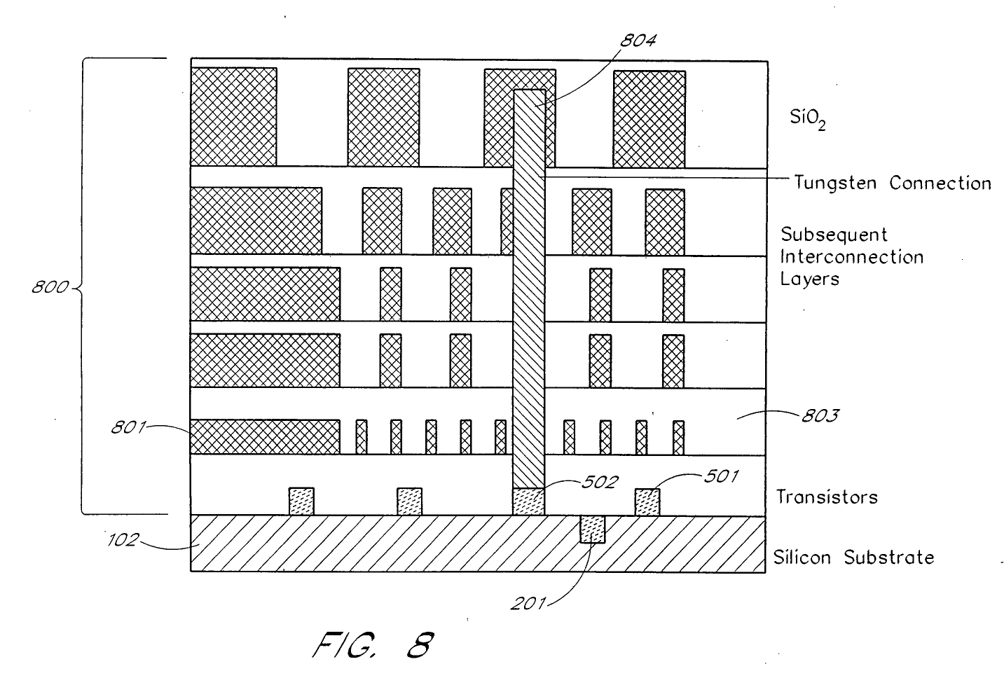

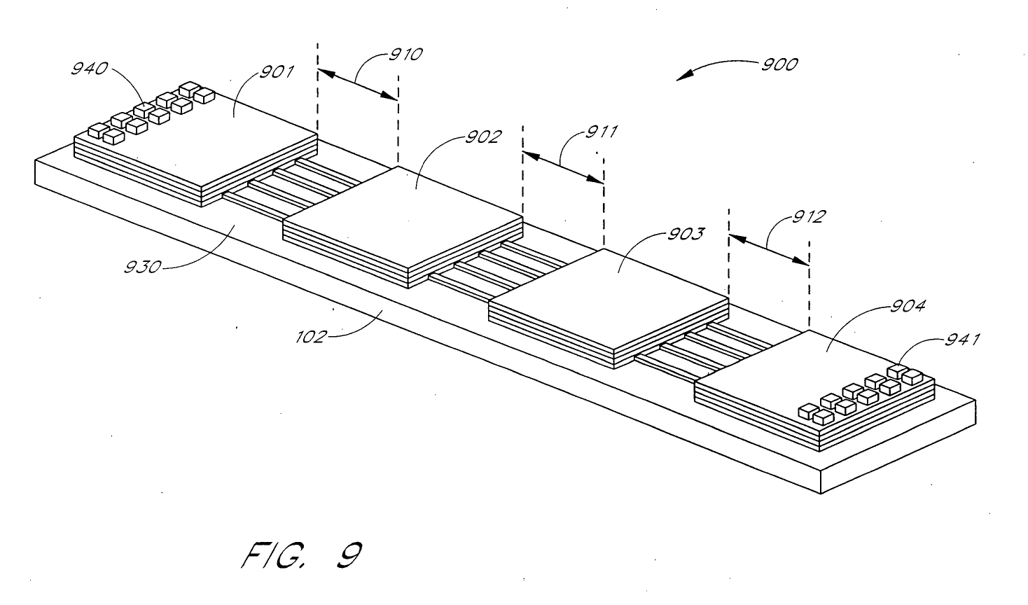

To reduce the possibility of short circuits, an insulating layer 701 (shown in FIG. 7) is added around the gate 501 and an insulating layer 702 is added around the gate 502. The insulating layers 701, 702 are added between the gates and the source/drain regions and are typically constructed from Si₃N₄. Finally, as shown in FIG. 7, a conducting layer 711 (using TiSi₂) is placed over the gate 501, and similar conducting layers 710 and 712 are placed over the source and drain regions of the transistor corresponding to the gate 501. Similarly, a conducting layer 721 is placed over the gate 502 and conducting layers 720 and 722 are placed over the source and drain of the transistor corresponding to the gate 502. The conducting layers 710-712 and 720-722 increase the performance and reduce the resistance of the transistors.

Once the transistors are created, they must be connected to each other using appropriate wiring. As shown in FIG. 8, a multi-layer interconnect structure 800 is made up of multiple layers of conducting traces (e.g., aluminum, copper, etc.) embedded in layers of an insulating material such as SiO₂. FIG. 8 shows, by way of example, a horizontal interconnection 801 that runs along one of the interconnection layers and a vertical connection 804 that runs vertically between the interconnection layers. Each of the interconnection layers is added one on top of the previous one and is polished by a mechanical and chemical process so as to allow the addition of further layers. Vertical interconnections, such as the vertical connection 804, are made of a conducting material (such as, for, example, tungsten) deposited in holes drilled through the interconnection layers so that traces in different layers can be connected. This expensive multi-layer wiring implementation is used so that complex designs can be realized with fewer concerns for trace topography and to incorporate wires of varying thickness (and in effect, resistance) to meet interconnection delay specifications.

FIG. 9 shows an integrated circuit 900 (on a substrate 948) having multiple active regions 901-904 connected by conductor regions 910-912. The conductor region 910 includes conducting traces, such as a trace 930, to electrically connect one or more elements in the active region 901 to one or more element in the active region 902. The conductor region 911 includes conducting traces to electrically connect elements in the active region 902 to element in the active region 903. The conductor region 912 includes conducting traces to electrically connect elements or traces in the active region 903 to element in the active region 904. One or more contact pads, such as a pad 940 are electrically connected to elements or conducting traces in the region 901. Optionally, one or more contact pads, such as a pad 941 are electrically connected to elements or conducting traces in the region 904. The active regions 901-904 can be constructed using process similar to that described in connection with FIGS. 2-8, or other integrated circuit manufacturing processes.

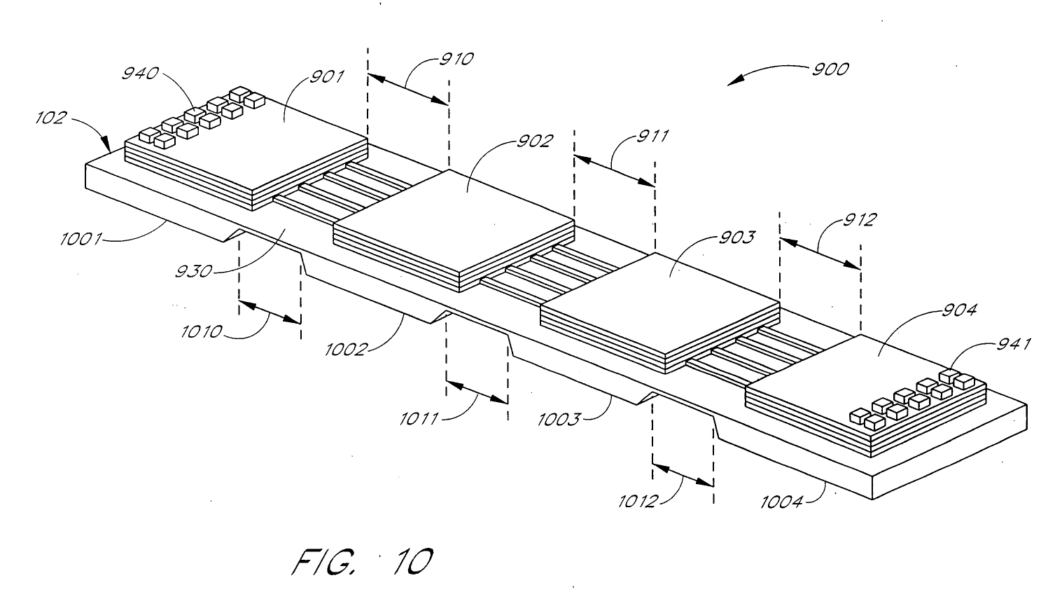

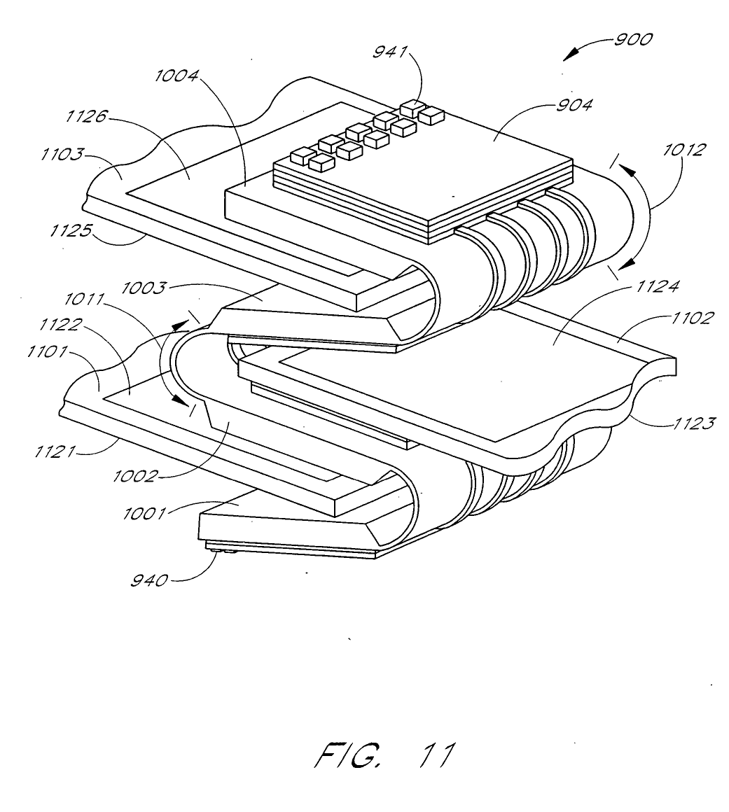

FIG. 10 shows the silicon substrate 948 after the thickness of the silicon substrate 948 has been reduced in a portion of the conductor regions 910-912 to produce flexible reduced-thickness regions 1010-1012 respectively. The three reduced-thickness regions 1010-1012 separate the substrate 948 into four folds 1001-1004 corresponding to the active regions 901-904 respectively.

The thickness of the silicon substrate in the reduced thickness regions 1010-1012 is thin enough such that the silicon becomes flexible without cracking or breaking and thus the substrate is foldable at the reduced-thickness regions 1010-1012. In one embodiment, the reduced thickness regions 1010-1012 are approximately 5 to 7 microns thick. If the conducting traces, and any insulating layers under the traces, running across the reduced-thickness regions 1010-1012 (such as, for example, the trace 930) are 4 to 5 microns thick, then the total thickness of the reduced-thickness regions 1010-1012 is approximately 9 to 12 microns thick.

In one embodiment, the edges of the reduced-thickness regions 1010-1012 are produced at an angle that matches a crystal plane of the substrate material (e.g., 45° for silicon) to reduce stress at the edges of the reduced-thickness regions 1010-1012. In one embodiment, the edges of the reduced-thickness regions 1010-1012 are produced at an angle or shape that is convenient given the manufacturing process used to thin the silicon.

The reduced thickness regions are produced by removing portions of the silicon substrate 948 from the back side of the substrate (that is, from the side opposite the active regions 901-904. In one embodiment, the reduced-thickness regions 1010-1012 are produced by grinding away portions of the silicon substrate. In one embodiment, the reduced-thickness regions 1010- 1012 are produced by cutting away portions of the silicon substrate. In one embodiment, the reduced-thickness regions 1010-1012 are produced by chemically etching away portions of the silicon substrate.

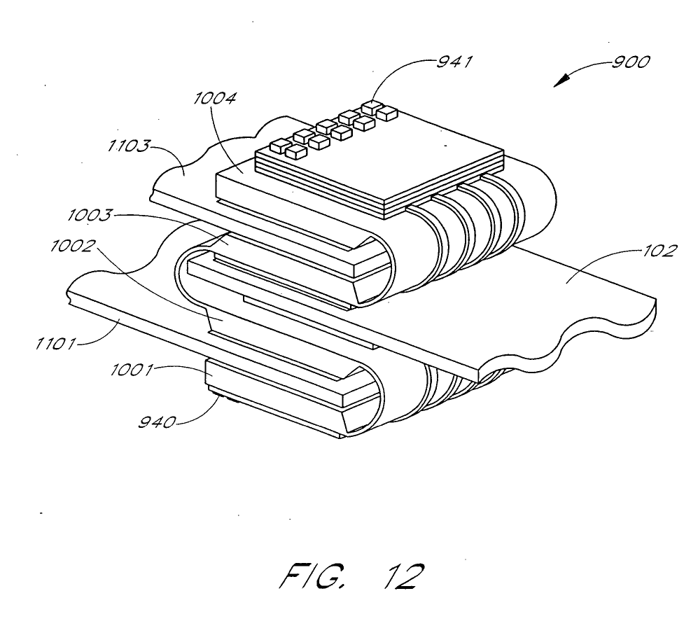

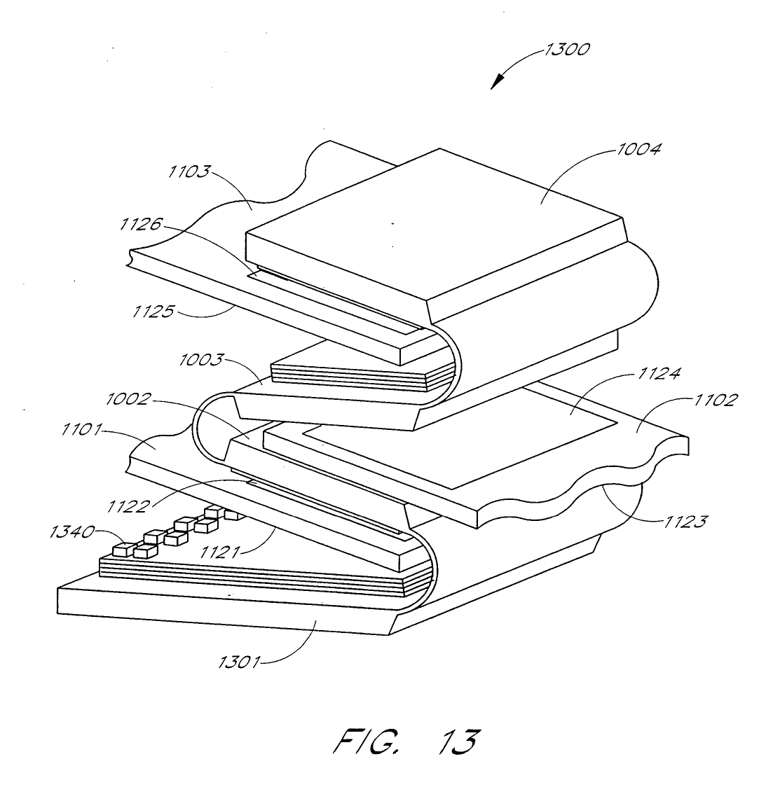

After the reduced-thickness regions 1010-1012 have been produced, the overall size (but not the volume) of the substrate 948 is reduced by folding the substrate 948 accordion-style at the reduced-thickness regions 1010-1012 where the substrate 948 is flexible. FIG. 11 shows the integrated circuit 900 partway through the folding process wherein the active region 901 is folded “outward” so that the region 901 remains exposed after the folding process. FIG. 12 shows the silicon substrate of FIG. 11 at the completion of the folding process. According to the folding scheme shown in FIGS. 11 and 12, if there are an even number of active regions, then the active region furthest from the region 901 will also remain exposed (thus, in FIG. 11, the region 904 remains exposed). If there are an odd number of active regions, then only the active regions 901 will remain exposed after the folding process is complete.

In one embodiment, inter-fold plates 1101-1103 are placed between the folds of the substrate 948. FIG. 11 shows an inter-fold plate 1101 between the folds 1001 and 1002, an inter-fold plate 1102 between the folds 1002 and 1003, and an inter-fold plate 1103 between the folds 1003 and 1004. The inter-fold plates 1101-1103 serve to increase the radius of curvature of the reduced-thickness regions 1010-1012 as the reduced-thickness regions 1010-1012 are folded. Maintaining a sufficient radius of curvature serves to reduce cracking and breaking of the silicon and the conducting traces in the folded reduced-thickness regions 1010-1012. In one embodiment, the inter-fold plates 1101-1103 also provide a path for heat conduction between the folds 1001-1004 and along the folds toward the outer edge of the plates. In one embodiment, heat sinks are attached to the outer portions of the inter-fold plates 1101-1103 to conduct heat away from the folds 1001-1004. In one embodiment, the inter-fold plates 1101-1103 are constructed from a thermally conductive material such as metal, ceramic, diamond, and the like.

As shown in FIG. 11, the radius of curvature of the reduced-thickness region 1010 (where the folds 1001 and 1002 meet back-to-back) is determined by the thickness of the fold 1001, the thickness of the fold 1002, and the thickness of the inter-fold plate 1101. Similarly, the radius of curvature of the reduced-thickness region 1012 is determined by the thickness of the fold 1003, the thickness of the fold 1004, and the thickness of the inter-fold plate 1103. However, the radius of curvature of the reduced-thickness region 1011 (where two active regions end up face-to-face) is determined primarily by the thickness of the thickness of the inter-fold plate 1102 but not the thickness of the folds 1002 and 1003. In one embodiment, inter-fold plates where active regions meet face-to-face, such as the inter-fold plate 1102, are made thicker than the inter-fold plates where plates meet back-to-back (such as the inter-fold plates 1101 and 1103) in order to provide a sufficient radius of curvature at teach reduced-thickness region to prevent cracking or breaking of the silicon or the conducting traces in the reduced-thickness region. In one embodiment, the inter-fold plates between folds that meet back-to-back (such as the inter-fold plates 1101 and 1103) are omitted.

Optionally, electrical insulation layers and/or bonding layers 1121 and 1122 are placed on either side of the inter-fold plate 1101. Optionally, electrical insulation layers and/or bonding layers 1123 and 1124 are placed on either side of the inter-fold plate 1102. Optionally, electrical insulation layers and/or bonding layers 1125 and 1126 are placed on either side of the inter-fold plate 1103.

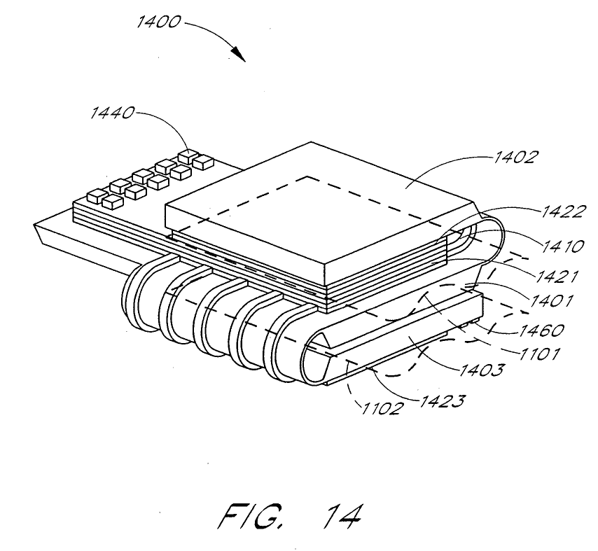

FIG. 13 shows an alternate folding scheme using an integrated circuit 1300. The integrated circuit 1300 is similar to the integrated circuit 900 except that the integrated circuit 1300 has an elongated first fold 1301 (in place of the fold 901) having the active region 901 and one or more conductor pads, such as a pad 1340, on an extended portion 1340 of the first fold 1301. As shown in FIG. 13, the integrated circuit 1300 is folded accordion-style such that the active region 901 and the active region 902 are folded face-to-face. The extended portion 1309 remains exposed. Thus, if there are an even number folds, then all of the active regions will be folded inward. If there are an odd number of folds, then the active region furthest from the region 901 (the region 904 in FIG. 13) will remain exposed. The extended portion 1309 provides the conducting pads, such as the conducting pad 1340 to allow packaging of the integrated circuit 1300. In addition, where there are an odd number of folds, one or more conducing pads (such as a pad 1320) can be placed on the last fold (the fold furthest from the first fold 1301) to provide additional electrical access to the integrated circuit.

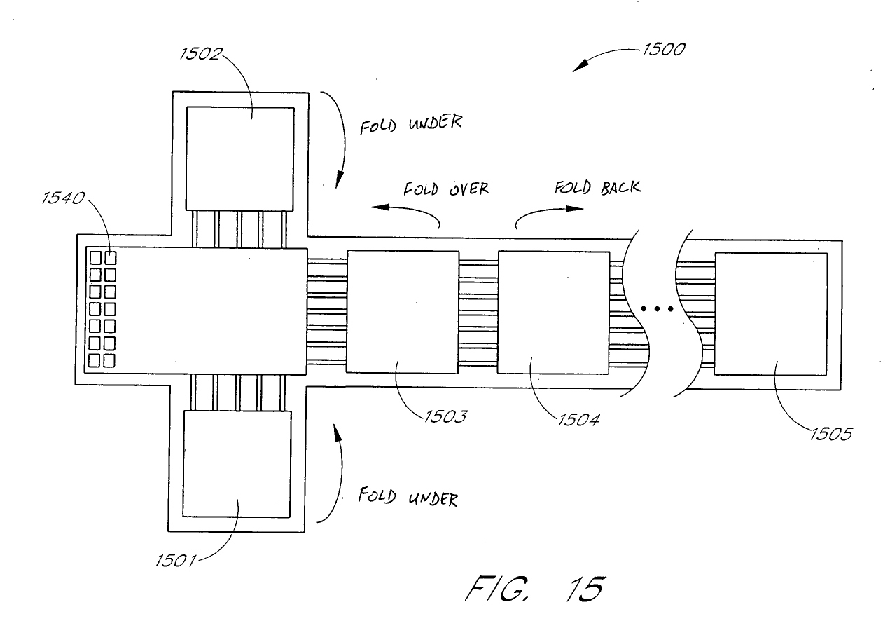

Folding schemes other than the schemes shown in FIGS. 11 and 13 will be apparent to one of ordinary skill in the art after reading the above disclosure in connection with FIGS. 1-14. For example, FIG. 14 shows an integrated circuit having an inner fold 1401, an outer fold 1402, and an outer fold 1403. The folds 1401-1403 have active regions 1421-1423 respectively. The inner fold 1401 is placed between the outer folds 1402 and 1403. Substrate regions between the folds 1401-1403 are reduced in thickness such that the substrate becomes flexible between the folds 1401-1403. The outer folds 1402 and 1403 are each folded over the inner fold 1401. In one embodiment, the fold 1403 is folded such that conducting pads, such as a pad 1460, on the fold 1403 remain exposed to allow electrical connections to the conducting pad 1460. In one embodiment, the inner fold 1401 includes an extended portion 1425 with conducting pads, such as a pad 1440 on the extended portion 1425. The pad 1440 on the extended portion 1425 remains exposed even if the fold 1402 or the fold 1403 is folded over the active region 1421.

FIG. 15 show an integrated circuit 1500 that is configured to be folded using a combination of the folding schemes shown in FIGS. 11, 13, and 14. The integrated circuit 1500 includes an inner fold, having an optional extended portion 1510. The integrated circuit also includes folds 1501-1503 attached by reduced-thickness regions to three sides of the inner fold 1501. The integrated circuit 1500 also includes a linear series of folds starting with a fold 1504 and ending with a fold 1505. The fold 1504 is attached to the fold 1503. The folds 1501-1503 are configured to be folded over the inner fold 1506. The folds 1504-1505 are folded accordion-style over the fold 1503. Any active regions that remain exposed on any of the folds 1501-1506 after folding can be provided with conducting pads to allow electrical connections to the integrated circuit 1500.

Although the foregoing has been a description and illustration of specific embodiments of the invention, various modifications and changes can be made thereto by persons skilled in the art, without departing from the scope and spirit of the invention as defined in the claims that follow.

1. A method for folding an integrated circuit substrate to change relatively large substrate into an integrated circuit having a much smaller form-factor than the original unfolded circuit, comprising:
producing a least one circuit element in a first active region of a substrate;
producing a least one circuit element in a second active region of said substrate, said first active region and said second active region being on a top side of said substrate, said top side separated from an underside of said substrate by a substrate thickness;
producing a least one conducting trace to connect said at least one circuit element in said first active region to said at least one circuit element in said second active region, said conducting trace lying on said top side;
thinning at least a portion of said substrate by removing material from said underside underneath said conducting trace to produce a reduced-thickness region; and
folding said substrate at said reduced-thickness region.

2. The method of claim 1, wherein said substrate comprises silicon.

3. The method of claim 1, wherein said at least one circuit element in said first active region is a transistor.

4. The method of claim 1, wherein said at least one circuit element in said first active region is a resistor.

5. The method of claim 1, wherein said reduced-thickness region is less than 20 microns thick.

6. The method of claim 1, further comprising inserting an inter-fold plate in between two folds of said substrate.

7. The method of claim 6, further comprising inserting at least one insulating layer between said inter-fold plate and said substrate.

8. The method of claim 6, further comprising inserting at least one insulating bonding between said inter-fold plate and said substrate.

9. The method of claim 6, wherein said inter-fold plate comprises a thermally-conductive material.

10. The method of claim 6, wherein said inter-fold plate comprises a metallic plate.

11. The method of claim 1, wherein said substrate is folded such that said first active region and said second active region remain exposed when said substrate is fully folded.

12. The method of claim 1, wherein said substrate is folded such that said first active region and said second active region are folded inward such that said first active region and said second active region are not exposed when said substrate is fully folded.

13. The method of claim 12, where said first active region comprises an extended portion having one or more conducting pads thereon, said extended portion remaining exposed when said substrate is fully folded.

14. The method of claim 1, further comprising a third active region on said top side, said substrate folded such that said first active region remains exposed when said substrate is fully folded.
